(19) United States
(12) Patent Application Publication
(10) Pub. No.: US 2025/0076370 A1
(43) Pub. Date: Mar. 6, 2025

(54) IC TEST METHOD AND IC TEST SYSTEM

(71) Applicant: Realtek Semiconductor Corp., HsinChu (TW)

(72) Inventors: Jian-Xing Huang, Hsinchu (TW); Ting-Ying Wu, HsinChu (TW); Chin-Yuan Lo, HsinChu (TW); Hsin-Hui Lo, HsinChu (TW)

(73) Assignee: Realtek Semiconductor Corp., HsinChu (TW)

(21) Appl. No.: 18/817,214

(22) Filed: Aug. 27, 2024

(30) Foreign Application Priority Data
Aug. 31, 2023 (TW) 112132935

(51) Int. Cl. G01R 31/28

(52) U.S. Cl. CPC G01R 31/2884

(57) ABSTRACT

An IC test method, comprising: electrically connecting a circuit board to a first IC; generating a first test signal to test the first IC; electrically connecting the circuit board to a first adaption board, and electrically connecting a second IC to the first adaption board, wherein a first connection mechanism between the first IC and the circuit board and a second connection mechanism between the second IC and the circuit board are different; and generating a second test signal to test the second IC by the control IC.

### BACKGROUND OF THE INVENTION

### 1. Field of the Invention

The present invention relates to an IC test method and an IC test system, and particularly related to an IC test method and an IC test system which can test ICs with different connections by an identical circuit board.

### 2. Description of the Prior Art

Conventionally, after the memory is packaged, the memory manufacturer must provide different circuit boards in order to test different memories. For example, if DDR4 (double data rate dynamic random-access memory 4) and DDR3 are required to be tested, memory manufacturers must provide circuit boards with different layouts since the distributions or numbers of connection points or pins of DDR4 and DDR3 are different. Otherwise, DDR4 and DDR3 may not be correctly electrically connected to the same circuit board for testing. However, such method not only increases manufacturing costs, but also requires the design of new test methods for different circuit boards, thereby increases the complexity and time cost of testing.

### SUMMARY OF THE INVENTION

One objective of the present invention discloses an IC test method which can share a circuit board for ICs with different connection mechanisms.

Another objective of the present invention discloses an IC test system which can share a circuit board for ICs with different connection mechanisms.

One embodiment of the present invention discloses an IC test method, comprising: electrically connecting a circuit board to a first IC; generating a first test signal to test the first IC; electrically connecting the circuit board to a first adaption board, and electrically connecting a second IC to the first adaption board, wherein a first connection mechanism between the first IC and the circuit board and a second connection mechanism between the second IC and the circuit board are different; and generating a second test signal to test the second IC by the control IC.

Another embodiment of the present invention discloses an IC test system, comprising: a circuit board, which can electrically connect to a first IC; a first adaption board, which can electrically connect to the circuit board and a second IC, wherein a first connection mechanism between the first IC and the circuit board and a second connection mechanism between the second IC and the circuit board are different; and a control IC, which can test the first IC via the circuit board and test the second IC via the first adaption board.

In view of the foregoing embodiments, by providing at least one adaption board, ICs with different connection mechanisms can be tested through the same circuit board, which can solve the issue of a conventional IC test method, which needs two different circuit boards for testing ICs with different connection mechanisms.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating IC test systems according to embodiments of the present invention.

FIG. 3 is a schematic diagram illustrating that different ICs have different connection mechanisms, according to one embodiment of the present invention.

FIG. 4 is a schematic diagram illustrating an IC test system according to another embodiment of the present invention.

FIG. 5 is a schematic diagram illustrating an IC test system according to still another embodiment of the present invention.

FIG. 6 is a flow chart illustrating an IC test method according to one embodiment of the present invention.

### DETAILED DESCRIPTION

Several embodiments are provided in following descriptions to explain the concept of the present invention. The method in following descriptions can be executed by programs stored in a non-transitory computer readable recording medium such as a hard disk, an optical disc or a memory. Additionally, the term “first”, “second”, “third” in following descriptions are only for the purpose of distinguishing different one elements, and do not mean the sequence of the elements. For example, a first device and a second device only mean these devices can have the same structure but are different devices.

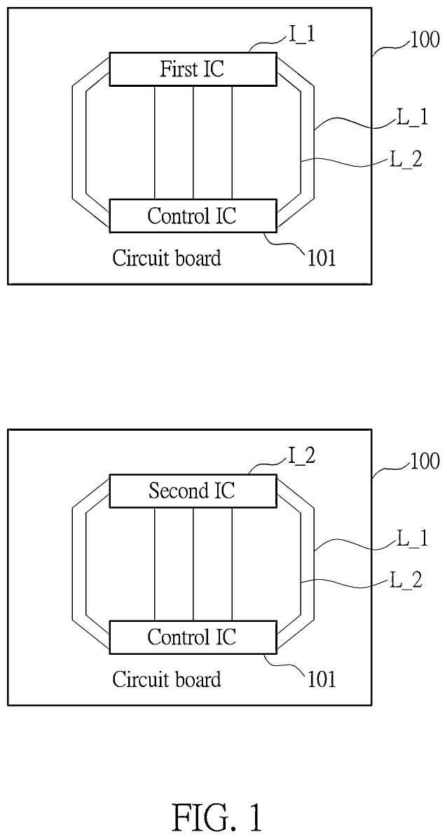

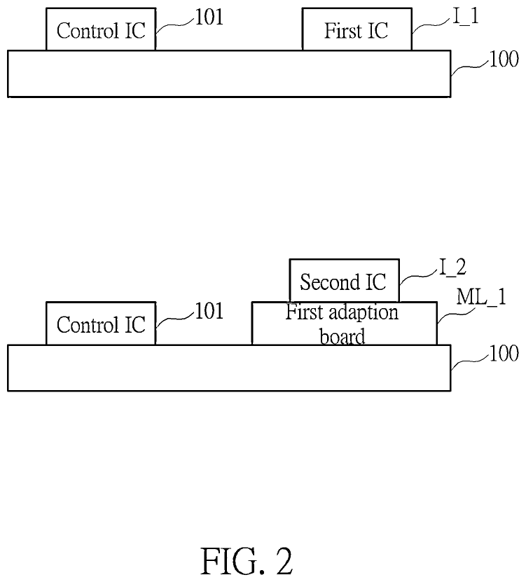

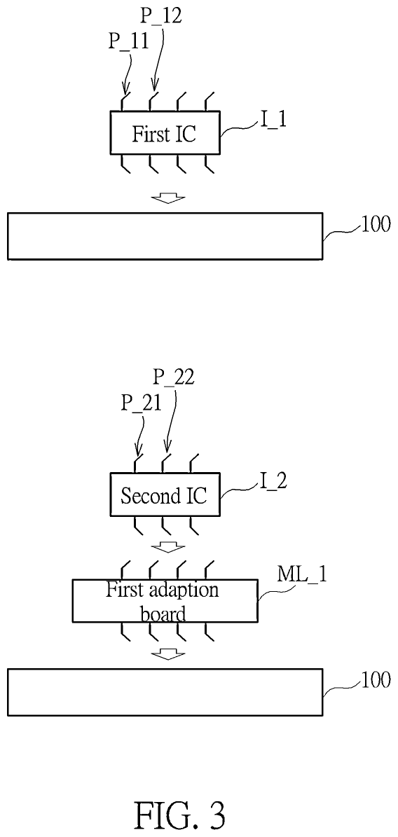

FIG. 1 and FIG. 2 are schematic diagrams illustrating IC test systems according to embodiments of the present invention. Please refer to FIG. 1 and FIG. 2 at the same time to understand the contents of the present invention for more clarity. As shown in FIG. 1, the first IC (Integrated Circuit) I_1 and the second IC I_2 can be tested through the control IC 101 provided on the circuit board 100. The circuit board 100 has a predetermined layout, for example, comprising a plurality of wires (only two wires L 1 and L 2 are symbolized). The first IC I_1 can be directly electrically connected to the circuit board 100, while the second IC I_2 cannot be directly electrically connected to the circuit board 100, but must be electrically connected to the circuit board 100 through a first adaption board ML_1. A first connection mechanism (or named as a connection manner) between the first IC I_1 and the circuit board 100 and a second connection mechanism between the second IC I_2 and the first adaption board ML_1 are different. Details about the connection mechanism will be explained for more detail in FIG. 3. Through the architectures of FIG. 1 and FIG. 2, the first IC I_1 and the second IC I_2 can be tested by the control IC 101 respectively.

FIG. 3 is a schematic diagram illustrating that different ICs have different connection mechanisms, according to one embodiment of the present invention. In the embodiment of FIG. 3, the number of the first pins (only two first pins P_11 and P 12 are symbolized for illustration) of the first IC I_1 and the number of the second pins (only two second pins P_21 and P_22 are symbolized for illustration) of the second IC I_2 are different. The first IC I_1 is electrically connected to the first adaption board ML_1 through the first pins P_11 and P_21, and the second IC I_2 is electrically connected to the first adaption board ML_1 through the second pins P_21 and P_22. For example, as shown in the upper figure of FIG. 3, the first IC I_1 has 8 pins, and the predetermined layout of the circuit board 100 allows the circuit board 100 to be directly electrically connected to the first IC I_1 with 8 pins. However, as shown in the lower diagram of FIG. 3, the second IC I_2 only has 6 pins and cannot be directly electrically connected to the circuit board 100. Therefore, the second IC I_2 needs to be disposed on the first adaption board ML_1 with 8 pins first, and then be electrically connected to the circuit board 100 through the first adaption board ML_1. However, the electrical connection between the first IC I_1, the second IC I_2 and the circuit board 100 can be realized through other connection interfaces and is not limited to pins. In addition, in one embodiment, the first IC I_1 and the second IC I_2 have the same number of pins, but their distribution positions are different, or they have the same number of pins and the same pin distribution positions, but the pins in the same position receive different signals.

As mentioned above, the first adaption board ML_1 can provide an electrical connection between the second IC I_2 and the circuit board 100. In one embodiment, the first adaption board ML_1 has a plurality of electronic components that can provide electrical connections and appropriate impedance matching, such as wires, resistors, capacitors or inductors. In other words, the first adaption board ML_1 can also be regarded as a circuit board. In one embodiment, a first resistance value, a first capacitance value and a first inductance value of the first adaption board ML_1 are lower than a second resistance value, a second capacitance value and a second inductance value of the circuit board 100. That is, the first adaption board ML_1 has a lower resistance value, a lower capacitance value and a lower inductance value. By this way, when the control IC 101 is used to test the second IC I_2, the test signal can have less signal offset or cause less electrical characteristic changes to the entire system, which will less affect the test results.

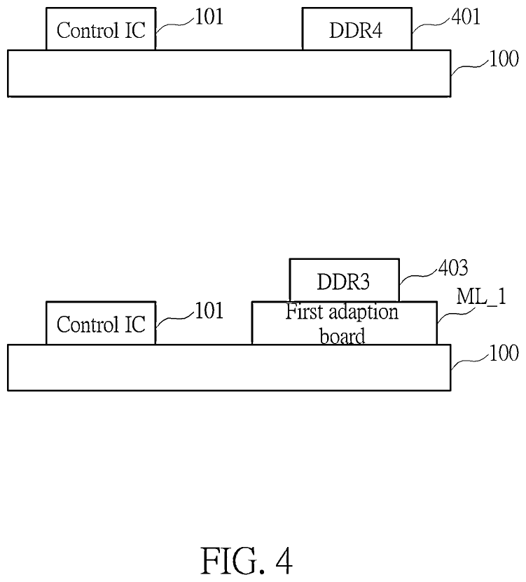

The first IC I_1 and the second IC I_2 may have various structures. In one embodiment, the first IC I_1 and the second IC I_2 are the same type of IC, that is, they have the same function. For example, the first IC I_1 and the second IC I_2 are both memories, image sensors, amplifying circuits or display driving circuits. In one embodiment, a data output rate of the first IC I_1 is higher than a data output rate of the second IC I_2. For example, as shown in the embodiment of FIG. 4, the first IC I_1 is a DDR4 401 and the second IC I_2 is a DDR3 403. In the embodiment shown in FIG. 4, the data output rate of DDR4 401 is higher than that of DDR3 403, thus needs a higher accuracy of the clock signal for transmitting and receiving data. Therefore, the tolerance of the DDR3 403 to the signal offset generated by the first adaption board ML_1 is higher than the tolerance of the DDR4 401 to the signal offset generated by the first adaption board ML_1. Accordingly, in this example, the circuit board 100 is designed for the first IC I_1 that has a low tolerance for signal offset. By this way, when testing the first IC I_1, less errors will be generated due to the first adaption board ML_1, thus a more accurate test result can be acquired.

In one embodiment, the above test includes function verification of the first IC I_1 and the second IC I_2. For example, verify whether the data output rates of the first IC I_1 and the second IC I_2 are within a predetermined range. If the first IC I_1 and the second IC I_2 are DDR4 401 and DDR4 403 respectively, it can be verified whether the access rates of the DDR4 401 and DDR4 403 are within a predetermined range. The aforementioned test may also include testing the output signal quality of the first IC I_1 and the second IC I_2. For example, after providing input signals to the first IC I_1 and the second IC I_2, observing whether the eye diagram of the output signal is clear or not.

In one embodiment, after the first IC I_1 and the second IC I_2 are tested and the test results of the first IC I_1 and the second IC I_2 indicate that they can operate normally, the IC manufacturer may provide the reference control parameters of the first IC I_1 and the second IC I_2 to the customer, when the IC I_1 and the second IC I_2 are handed over to the customer. By this way, after the customer assembles the first IC I_1 and the second IC I_2 into other electronic devices, the customer can directly control the first IC I_1 and the second IC I_2 with the reference control parameters, or generate the required control parameters based on the reference control parameters to control the first IC I_1 and the second IC I_2.

However, the second IC I_2 is electrically connected to the circuit board 100 through the first adaption board ML_1, and the first adaption board ML_1 may cause signal offset, or change characteristics of the entire system (such as resistance, capacitance, or inductance). Therefore, in one embodiment, a first resistance value, a first capacitance value or a first inductance value generated by the first adaption board ML_1 is first calculated, and the control IC 101 is used to generate at least one reference control parameter of the second IC IC_2 according to the first resistance value, the first capacitance value or the first inductance value. For example, the first resistance value, the first capacitance value or the first resistance value can be obtained by measuring the resistance value, the capacitance value or the inductance value of a circuit board or electronic device in the prior art. Then, the control IC 101 generates reference control parameters based on possible signal offsets generated by the first resistance value, the first capacitance value, or the first inductance value.

In another embodiment, a signal offset caused by the first adaption board ML_1 is calculated, and the control IC 101 is used to generate at least one reference control parameter of the second IC I_2 according to the signal offset. For example, a signal input point and a signal output point can be preset on the first adaption board ML_1, then provide an input signal to the signal input point, and then measure differences between a frequency, an amplitude or a phase of the input signal and a frequency, an amplitude or a phase of the output signal, to calculate the signal offset caused by the first adaption board ML_1.

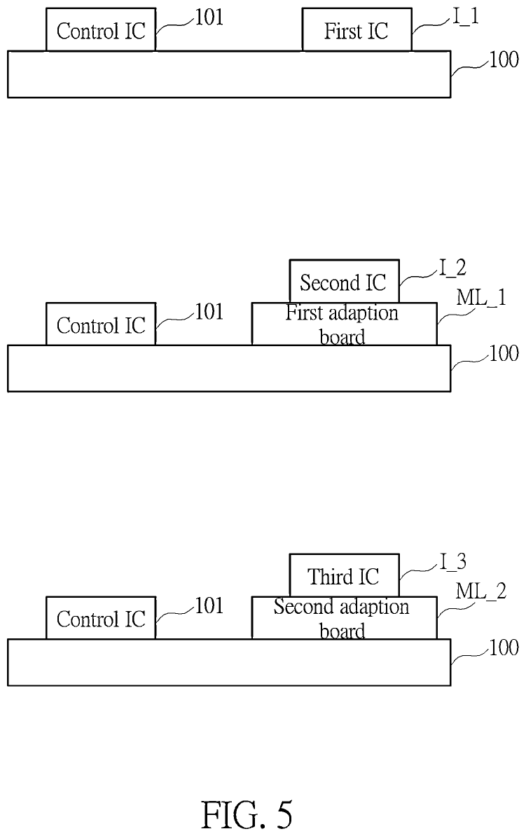

The above-mentioned embodiments are explained using two different ICs and an adaption board. However, the concepts disclosed in the above embodiments can be applied to more than two different ICs and more than one adaption board. FIG. 5 is a schematic diagram illustrating an IC test system according to still another embodiment of the present invention. As shown in FIG. 5, in addition to the first IC I_1, the second IC I_2 and the first adaption board ML_1 in FIG. 1, a second adaption board ML_2 is provided for testing the third IC I_3.

The third IC I_3 must be electrically connected to the circuit board 100 through a second adaption board ML_2. A third connection mechanism between the third IC I_3 and the circuit board 100 is different from a first connection mechanism between the first IC I_1 and the circuit board 100, and a second connection mechanism between the second IC I_2 and the circuit board 100. Details about the connection mechanism are explained in FIG. 3. Through the architecture of FIG. 5, the first IC I_1, the second IC I_2 and the third IC I_3 can be tested by the control IC 101 respectively.

The second adaption board ML_2 can provide an electrical connection between the third IC I_3 and the circuit board 100. The second adaption board ML_2 may have a plurality of electronic components that can provide electrical connections and appropriate impedance matching, such as resistors, capacitors, and inductors. In other words, the second adaption board ML_2 can also be regarded as a circuit board. In one embodiment, the resistance value, the capacitance value and the inductance value of the second adaption board ML_2 are lower than a second resistance value, a second capacitance value and a second inductance value of the circuit board 100. That is, the second adaption board ML_2 has a lower resistance value, a lower capacitance value and a lower inductance value. By this way, when the control IC 101 is used to test the third IC I_3, the test signal can have less signal offset, which will less affect the test results.

The first IC I_1, the second IC I_2, and the third IC I_3 may have various structures. In one embodiment, the first IC I_1, the second IC I_2 and the third IC I_3 are the same type of IC, that is, they have the same function. For example, the first IC I_1, the second IC I_2 and the third IC I_3 are all memories, image sensors, amplification circuits or display driving circuits. In one embodiment, a data output rate of the first IC I_1 is higher than a data output rate of the third IC I_3.

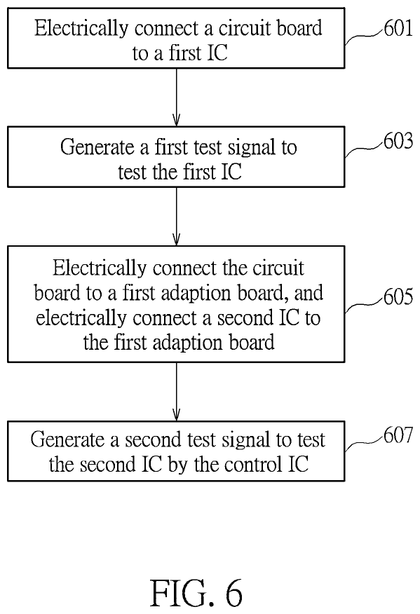

The aforementioned circuit board 100 and control IC 101 can be regarded as an IC testing system, and an IC testing method can be obtained according to the aforementioned embodiments. FIG. 6 is a flow chart illustrating an IC test method according to one embodiment of the present invention, which includes the following steps:

### Step 601

Electrically connect a circuit board (for example, the circuit board 100) to a first IC (for example, the first IC I_1).

### Step 603

Generate a first test signal to test the first IC (e.g., by the control IC 101).

For example, generate the first test signal by the control IC.

### Step 605

Electrically connect the circuit board to a first adaption board (for example, the first adaption board ML_1), and electrically connect a second IC (for example, the second IC I_2) to the first adaption board.

A first connection mechanism between the first IC and the circuit board and a second connection mechanism between the second IC and the circuit board are different

### Step 607

Generate a second test signal to test the second IC by the control IC.

For example, generate the second test signal by the control IC.

Other detail steps can be derived based on the foregoing embodiments, thus are omitted for brevity here.

In view of the foregoing embodiments, by providing at least one adaption board, ICs with different connection mechanisms can be tested through the same circuit board, which can solve the issue of a conventional IC test method, which needs two different circuit boards for testing ICs with different connection mechanisms.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An IC test method, comprising:
electrically connecting a circuit board to a first IC;
generating a first test signal to test the first IC;
electrically connecting the circuit board to a first adaption board, and electrically connecting a second IC to the first adaption board, wherein a first connection mechanism between the first IC and the circuit board and a second connection mechanism between the second IC and the circuit board are different; and
generating a second test signal to test the second IC by the control IC.

2. The IC test method of claim 1, wherein a data output rate of the first IC is higher than a data output rate of the second IC.

3. The IC test method of claim 1, wherein the first IC is a DDR4 and the second IC is a DDR3.

4. The IC test method of claim 1, wherein the first IC and the second IC are ICs with an identical type.

5. The IC test method of claim 1, wherein a number of at least one first pin of the first IC is different from a number of at least one second pin of the second IC, wherein the first IC is electrically connected to the first adaption board via the first pin, and the second IC is electrically connected to the first adaption board via the second pin.

6. The IC test method of claim 1, wherein a first resistance value, a first capacitance value and a first inductance value of the first adaption board are lower than a second resistance value, a second capacitance value and a second inductance value of the circuit board.

7. The IC test method of claim 1, first comprising:
computing a first resistance value, a first capacitance value or a first inductance value of the first adaption board; and
generating at least one reference control parameter of the second IC according to the first resistance value, the first capacitance value or the first inductance value by a control IC.

8. The IC test method of claim 1, further comprising:
computing a signal offset caused by the first adaption board; and
generating at least one reference control parameter of the second IC according to the signal offset by a control IC.

9. The IC test method of claim 1, further comprising:
electrically connecting the circuit board to a second adaption board, and electrically connecting a third IC to the second adaption board, wherein a third connection mechanism between the third IC and the circuit board is different from the first connection mechanism and the second connection mechanism; and
testing the third IC by a control IC.

10. An IC test system, comprising:
a circuit board, which can electrically connect to a first IC;
a first adaption board, which can electrically connect to the circuit board and a second IC, wherein a first connection mechanism between the first IC and the circuit board and a second connection mechanism between the second IC and the circuit board are different; and
a control IC, which can test the first IC via the circuit board and test the second IC via the first adaption board.

11. The IC test system of claim 10, wherein a data output rate of the first IC is higher than a data output rate of the second IC.

12. The IC test system of claim 10, wherein the first IC is a DDR4 and the second IC is a DDR3.

13. The IC test system of claim 10, wherein the first IC and the second IC are ICs with an identical type.

14. The IC test system of claim 10, wherein a number of at least one first pin of the first IC is different from a number of at least one second pin of the second IC, wherein the first IC is electrically connected to the first adaption board via the first pin, and the second IC is electrically connected to the first adaption board via the second pin.

15. The IC test system of claim 10, wherein a first resistance value, a first capacitance value and a first inductance value of the first adaption board are lower than a second resistance value, a second capacitance value and a second inductance value of the circuit board.

16. The IC test system of claim 10, further comprising:
a second adaption board, which can electrically connect to the circuit board and a third IC, wherein a third connection mechanism between the third IC and the circuit board is different from the first connection mechanism and the second connection mechanism.
